(19) United States
(12) Patent Application Publication
(10) Pub. No.: US 2019/0393285 A1
(43) Pub. Date: Dec. 26, 2019

(54) DISPLAY DEVICE, ELECTRONIC DEVICE, AND MANUFACTURING METHOD OF DISPLAY DEVICE

(71) Applicant: Sony Corporation, Tokyo (JP)

(72) Inventor: Takayoshi Kato, Kanagawa (JP)

(21) Appl. No.: 16/479,164

(22) PCT Filed: Dec. 28, 2017
(86) PCT No.: PCT/JP2017/047363

§ 371 Date: Jul. 18, 2019

(30) Foreign Application Priority Data
Jan. 26, 2017 (JP) 2017-012321

(51) Int. Cl. H01L 27/32; H01L 51/52

(52) U.S. Cl. CPC H01L 27/3246; H01L 51/5275; H01L 27/322

(57) ABSTRACT

To enable realization of higher quality display.

Provided is a display device including a plurality of light emitting elements formed on a substrate, and a first film laminated on the plurality of light emitting elements, in which a convex portion protruding upward exists in a partial region of a light emitting region of the light emitting elements, and an upper surface of the first film has a substantially spherical convex shape corresponding to the convex portion.

### TECHNICAL FIELD

The present disclosure relates to a display device, an electronic device, and a manufacturing method of a display device.

### BACKGROUND ART

In a display device, in order to improve light extraction efficiency, a structure in which a microlens (ML) is provided in each light emitting direction for each pixel has been proposed. For example, Patent Document 1 discloses a manufacturing method of an organic electroluminescence (EL) display device in which shapes of regions corresponding to pixels of an underlying layer are hemispherical convex shapes, and an organic EL element and a protective film are formed on the underlying layer. According to this method, the convex shape of the underlying layer is transferred to a top surface of the protective film, and the top surface of the protective film functions as a ML located right above each organic EL element.

### CITATION LIST

### Patent Document

Patent Document 1: Japanese Patent Application Laid-Open

### SUMMARY OF THE INVENTION

### Problems to be Solved by the Invention

However, in the technology disclosed in Patent Document 1, the organic layer of the organic EL element is laminated on the hemispherical convex shape of the underlying layer. The organic layer is laminated on a curved surface, so that the organic layer is not laminated with a uniform thickness, and there is a fear that variation in luminance and chromaticity of each light emitting element is large. Accordingly, as a result, the luminance and the chromaticity are nonuniform in the display surface, making it difficult to realize a high-quality display device.

In view of the above circumstances, in a display device, it has been required to realize higher quality display with improved light extraction efficiency by forming an ML by a more preferable method. Therefore, the present disclosure proposes a novel and improved display device, an electronic device, and a manufacturing method of a display device capable of realizing higher quality display.

### Solutions to Problems

According to the present disclosure, provided is a display device including a plurality of light emitting elements formed on a substrate, and a first film laminated on the plurality of light emitting elements, in which a convex portion protruding upward exists in a partial region of a light emitting region of the light emitting elements, and an upper surface of the first film has a substantially spherical convex shape corresponding to the convex portion.

Furthermore, according to the present disclosure, provided is an electronic device including a display device that performs display on the basis of an image signal, the display device including a plurality of light emitting elements formed on a substrate, and a first film laminated on the plurality of light emitting elements, in which a convex portion protruding upward exists in a partial region of a light emitting region of the light emitting elements, and an upper surface of the first film has a substantially spherical convex shape corresponding to the convex portion.

Furthermore, according to the present disclosure, provided is a manufacturing method of a display device including a step of forming a plurality of light emitting elements on a substrate, and a step of laminating a first film on the plurality of light emitting elements, in which a convex portion protruding upward is formed in a partial region of a light emitting region of the light emitting elements, in which in the step of laminating of the first film, the first film is laminated on the convex portion so that an upper surface of the first film has a substantially spherical convex shape corresponding to the convex portion.

According to the present disclosure, in a display device prepared by laminating a first film (for example, a protective film) on a light emitting element, a convex portion protruding upward is formed in a partial region of a light emitting region of the light emitting element, and the first film is laminated on the convex portion when the first film is laminated so that a substantially spherical convex shape corresponding to the convex portion is formed on an upper surface of the first film. The convex shape of the upper surface of the first film formed right above the light emitting element can function as an ML. In this manner, according to the present disclosure, the ML is formed in a self-aligning manner in accordance with the convex portion provided in a partial region of the light emitting region of the light emitting element. Accordingly, it is possible to accurately align the light emitting element and the ML. At this time, the region of the light emitting region of the light emitting element where the convex portion is not provided can be plain, so that the formation of the organic layer in the light emitting region is less likely to vary as compared with the method disclosed in Patent Document 1, and the characteristics of each light emitting element are also less likely to vary. Therefore, according to the present disclosure, a display device capable of high quality display can be realized.

### Effects of the Invention

As described above, according to the present disclosure, higher quality display can be realized. Note that the above-mentioned effects are not necessarily limited, and, in addition to the above effects or instead of the above effects, any of the effects shown in this specification, or other effects that can be grasped from this specification may be exhibited.

### BRIEF DESCRIPTION OF DRAWINGS

FIG. 1 is a view for describing a manufacturing method of a display device according to a first embodiment.

FIG. 2 is a view for describing the manufacturing method of the display device according to the first embodiment.

FIG. 3 is a view for describing the manufacturing method of the display device according to the first embodiment.

FIG. 4 is a view for describing the manufacturing method of the display device according to the first embodiment.

FIG. 5 is a view for describing an effect of an ML in the display device according to the first embodiment.

FIG. 6 is a view for describing a cross-sectional shape of a main part of the display device according to the first embodiment.

FIG. 7 is a view for describing dimensions of a shape in a horizontal surface of the main part of the display device according to the first embodiment.

FIG. 8 is a view showing another example of a shape of a remaining film in a case of being viewed from above.

FIG. 9 is a view showing another example of the shape of the remaining film in a case of being viewed from above.

FIG. 10 is a view for describing a manufacturing method of a display device according to a second embodiment.

FIG. 11 is a view for describing the manufacturing method of the display device according to the second embodiment.

FIG. 12 is a view for describing the manufacturing method of the display device according to the second embodiment.

FIG. 13 is a view for describing the manufacturing method of the display device according to the second embodiment.

FIG. 14 is a view for describing the manufacturing method of the display device according to the second embodiment.

FIG. 15 is a view for describing the manufacturing method of the display device according to the second embodiment.

FIG. 16 is a view for describing the manufacturing method of the display device according to the second embodiment.

FIG. 17 is a view showing an appearance of a smartphone which is an example of an electronic device to which a display device according to each embodiment can be applied.

FIG. 18 is a view showing an appearance of a digital camera which is another example of an electronic device to which a display device according to each embodiment can be applied.

FIG. 19 is a view showing an appearance of a digital camera which is another example of an electronic device to which a display device according to each embodiment can be applied.

FIG. 20 is a view showing an appearance of an HMD which is another example of an electronic device to which a display device according to each embodiment can be applied.

### MODE FOR CARRYING OUT THE INVENTION

Preferred embodiments of the present disclosure will be described in detail below with reference to the accompanying drawings. Note that, in the present specification and the drawings, the same reference numerals are given to the constituent elements having substantially the same functional configuration, and redundant explanations are omitted.

Note that, in the following description, in the configuration of the display device, a laminating direction of each layer is also referred to as a vertical direction. In this case, in the vertical direction, a direction in which each layer is laminated is also referred to as an upward direction, and an opposite direction is also referred to as a downward direction. Furthermore, a direction perpendicular to the vertical direction is also referred to as a horizontal direction, and a surface parallel to the horizontal direction is also referred to as a horizontal surface. Furthermore, in this specification, in a case where it is described that a certain layer and another layer are laminated, another layer exists on an upper layer or a lower layer of a certain layer, or the like, the expression may mean a state where these layers are laminated in direct contact, or may also mean a state where these layers are laminated with another layer interposed between these layers.

Here, in this specification, an ultra-compact display device means a display device having a panel size of about 0.2 inches to about 2 inches, for example. The pixel size of the ultra-compact display device may be, for example, about 20 μm or less. The ultra-compact display device can be suitably applied to, for example, a display unit of a head mounted display (HMD), an electronic view finder (EVF) of a digital camera, or the like. Furthermore, an ultra-compact display device means a display device having a panel size of about 2 inches to about 7 inches, for example. The pixel size of a compact display device may be, for example, about 30 μm to 70 μm. Furthermore, a middle display device means a display device having a panel size of about 7 inches to about 15 inches, for example. The pixel size of a middle display device may be, for example, about 50 μm to about 100 μm. The compact or medium display device can be suitably applied to, for example, a display unit of a smartphone, a tablet personal computer (PC), or the like.

Note that the description will be given in the following order.

1. Background conceived for the present invention

2. First embodiment

2-1. Manufacturing method of display device

2-2. Configuration of main part of display device

2-2-1. Shape of cross section

2-2-2. Shape of plane

3. Second embodiment

4. Application example

5. Supplement

### 1. Background Conceived for the Present Invention

Prior to describing the preferred embodiments of the present disclosure, the background conceived for the present invention by the present inventors will be described.

As described above, in a display device, in order to improve light extraction efficiency, a structure in which an ML is provided for each pixel has been proposed. For example, as a method of providing the ML in an organic EL display device, in a case of a facing color filter (CF) type organic EL display device, considered is a method of forming the ML on facing substrates on which the CFs are formed. Alternatively, in a case of an on chip color filter (OCCF) type organic EL display device, considered is a method of forming the ML as an on chip lens by a method of laminating a lens material including a photosensitive resin or the like on a substrate, and performing reflowing after patterning, a method of laminating a lens material on a substrate, and performing patterning using a gray scale mask, or the like.

Meanwhile, development of ultra-compact display devices (so-called micro displays) applied to, for example, a display unit of an HMD, an EVF of a digital camera or the like has been actively conducted in recent years. Among them, an organic EL display device can realize high contrast and high speed response as compared with a liquid crystal display device, so that an organic EL display device is attracting attention as an ultra-compact display device mounted in such an electronic device.

In such an ultra-compact organic EL display device (hereinafter, also referred to as an organic EL micro display), in order to realize compact but high-definition display, a pixel pitch is being miniaturized to, for example, about 10 μm or less. As the pixel pitch becomes finer as described above, in any of the above-described methods, it becomes difficult to accurately align an organic EL element which is a light emitting element and an ML. If the accuracy of the alignment between the light emitting element and the ML is reduced, the optical characteristics of a panel such as luminance and chromaticity, furthermore the viewing angle characteristics are deteriorated, which is a serious quality problem. As described above, in an organic EL microdisplay having a small pixel pitch, the accuracy of the alignment between the light emitting element and the ML can be a major factor affecting the quality.

As a method for accurately aligning the light emitting element and the ML, for example, a method disclosed in Patent Document 1 is disclosed. As described above, Patent Document 1 discloses a manufacturing method of an organic EL display device in which shapes of regions corresponding to pixels of an underlying layer are hemispherical convex shapes, and a light emitting element (organic EL element) and a protective film are formed on the underlying layer. According to this method, the convex shape of the underlying layer is transferred to a top surface of the protective film, and the top surface of the protective film functions as an ML located right above each light emitting element. That is, in this method, since the ML is formed in a self-aligning manner, it is possible to improve the accuracy of the alignment between the light emitting element and the ML.

However, there are several concerns with such a method. The first concern is that, as described above, in the method disclosed in Patent Document 1, since the light emitting element is formed on the curved surface, there is a fear that variations in characteristics of the light emitting element may occur.

The second concern is that it is considered that applying the method disclosed in Patent Document 1 is difficult in a case where the pixel pitch is small. Specifically, in the method disclosed in Patent Document 1, an anode that is a lower layer electrode is formed on the entire surface of a convex shape of an underlayer, and in a state where a part of the surface of the anode is opened, a cathode that is an electrode of an organic layer and an upper layer is sequentially laminated so that an organic EL element is formed. That is, in the organic EL display device disclosed in Patent Document 1, the area of an opening of the anode in the organic EL element, that is, the area of the light emitting region is smaller than the area of the convex shape of the underlying layer. In other words, in the organic EL display device, the pixel pitch cannot be made smaller than the pitch at which the convex shape is formed in the underlying layer. Then, Patent Document 1 discloses that it is preferable that the width of a bottom portion of the convex shape in the underlying layer (the width on the substrate surface) be 5.0 μm or more and 30 μm or less. Accordingly, it can be said that the method disclosed in Patent Document 1 is not suitable in a case of reducing the pixel pitch to 10 μm or less, for example.

As described above, it can be said that a forming method of the ML with which the alignment between the light emitting element and the ML can be accurately performed has not sufficiently been studied, particularly in an ultra-compact display device. The inventors of the present invention diligently studied such a forming method of the ML with which the alignment between the light emitting element and the ML can be accurately performed, and as a result, conceived of the present disclosure. According to the present disclosure, it is possible to improve the alignment accuracy of the alignment between the light emitting element and the ML even in an ultra-compact display device, without causing concern such as the above-described variations of the characteristics of the light emitting element. Accordingly, it is possible to realize a display device capable of higher quality display with improved light extraction efficiency.

Preferable embodiments of the present disclosure conceived by the present inventors will be described below in detail. Note that, in the following description, an embodiment related to an organic EL display device will be described as an example. However, the present disclosure is not limited to this example, and the technology according to the present disclosure can be applied to other types of display devices as long as a pixel is configured by forming a self-luminous element on a substrate.

### 2. First Embodiment

(2-1. Manufacturing Method of Display Device)

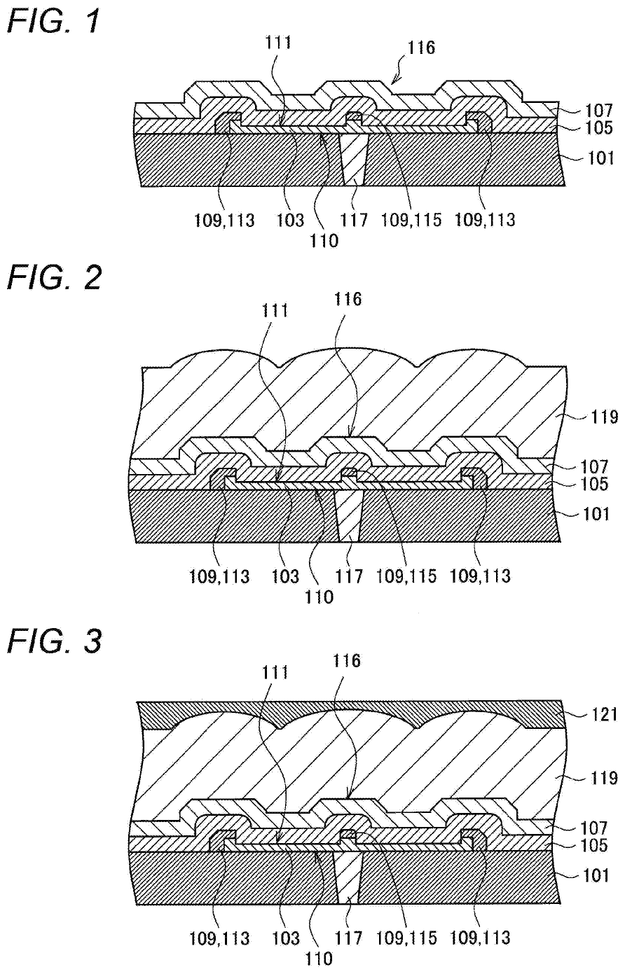

A manufacturing method of a display device according to a first embodiment of the present disclosure will be described with reference to FIGS. 1 to 4. FIGS. 1 to 4 are views for describing the manufacturing method of the display device according to the first embodiment. FIGS. 1 to 4 schematically show a cross section parallel to the vertical direction of the display device according to the first embodiment in the order of steps in the manufacturing method of the display device, and represent the process flow in the manufacturing method. Note that, in FIGS. 1 to 4, in order to describe characteristic steps of the manufacturing method, only a part of the structure related to these steps in the display device is described.

In the manufacturing method of the display device according to the first embodiment, first, a light emitting element 110 including a driving circuit (not shown) and an organic EL element is formed on a first substrate (not shown) (FIG. 1). The driving circuit is for driving the light emitting element 110 and includes a thin film transistor (TFT) and the like. An insulating layer 101 is laminated on the driving circuit formed. Then, the light emitting element 110 is formed on the insulating layer 101.

Note that, before the light emitting element 110 is formed, a via 117 for electrically connecting the driving circuit and the light emitting element 110 is formed in the insulating layer 101. The via 117 may be formed by various known methods. For example, the via 117 may be formed by providing an opening in the insulating layer 101 by the dry etching method, then, embedding a conductive material such as tungsten (W) to the opening by the sputtering method, and planarizing surfaces of the insulating layer 101 and the embedded conductive material by chemical mechanical polishing (CMP).

The light emitting element 110 is formed by a first electrode 103, an organic layer 105 functioning as a light emitting layer, and a second electrode 107 laminated in this order. The organic layer 105 includes an organic light emitting material and is configured to emit white light. The first electrode 103 functions as an anode. The second electrode 107 functions as a cathode. Here, the display device according to the first embodiment is a top emission type. Accordingly, the first electrode 103 is formed by a material that can reflect light from the organic layer 105. Furthermore, the second electrode 107 is formed by a material that can transmit light from the organic layer 105.

Specifically, the first electrode 103 is formed on the insulating layer 101. An insulating layer 109 provided with an opening 111 such that at least a part of the first electrode 103 is exposed is laminated on the first electrode 103, and the organic layer 105 and the second electrode 107 are laminated on the first electrode 103 and the insulating layer 109 so as to contact the first electrode 103 exposed at the bottom portion of the opening 111. That is, the light emitting element 110 has a structure in which the first electrode 103, the organic layer 105, and the second electrode 107 are laminated in this order in the opening 111 of the insulating layer 109. A region corresponding to the opening 111 of the insulating layer 109 of the light emitting element 110 corresponds to the light emitting region of the light emitting element 110.

One light emitting element 110 constitutes one pixel. Although FIGS. 1 to 4 only show a region corresponding to one light emitting element 110, in reality, a plurality of light emitting elements 110 are arrayed in a region corresponding to a display region on a first substrate two-dimensionally at predetermined pixel pitches. Furthermore, the above-described insulating layer 109 functions as a pixel definition film provided between the pixels and defining the area of the pixel.

Note that the first electrode 103 is patterned corresponding to each pixel, and the driving circuit is electrically connected to each patterned first electrode 103 via the via 117 provided in the insulating layer 101. Each light emitting element 110 may be driven by appropriately applying a voltage to each first electrode 103 by the driving circuit.

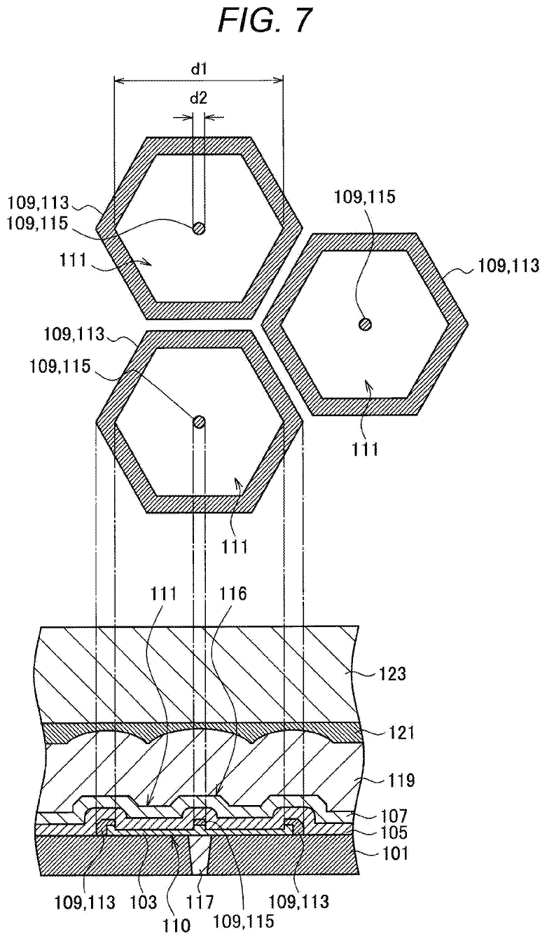

Here, in the first embodiment, when the opening 111 is provided in the insulating layer 109, the insulating layer 109 remains in a partial region in the opening 111. In the example shown in the drawing, the insulating layer 109 remains in one place in a partial region substantially at the center in the horizontal surface of the opening 111 so that the shape in a case of being viewed from above is a substantially circular (the state viewed from above will be described later with reference to FIG. 7). Hereinafter, for the sake of distinction, a portion of the insulating layer 109 that defines the opening 111 (in other words, a portion functioning as a pixel definition film) is also described as a pixel definition film 113, and a portion of an island shape remaining in the opening 111 is also described as a remaining film 115.

The remaining film 115 is formed in a partial region in the opening 111 so that the portion where the remaining film 115 exists on the top surface of the first electrode 103 protrudes upward further than the other region in the opening 111. That is, a convex shape of the remaining film 115 can be formed in a partial region in the opening 111 of the first electrode 103. Accordingly, when the organic layer 105 and the second electrode 107 are laminated thereon, the organic layer 105 and the second electrode 107 also have a convex shape corresponding to the protruding shape of the remaining film 115. In other words, the protruding shape by the remaining film 115 is transferred to the shapes of the organic layer 105 and the second electrode 107. Therefore, as shown in the drawing, the light emitting element 110 has one convex portion 116 protruding upward from the other regions, in a partial region of the light emitting region. That is, the light emitting element 110 has a configuration in which the convex portion 116 exists in a partial region in the substantially flat light emitting region.

Note that, in the first embodiment, steps up to the formation of the light emitting element 110 on the first substrate shown in FIG. 1 may be similar to a general existing method except that the convex portion 116 of the remaining film 115 described above is formed.

For example, the first substrate may be formed by a silicon substrate, a quartz glass substrate, a high strain point glass substrate, a soda glass (a mixture of Na₂O, CaO, and SiO₂) substrate, a borosilicate glass (a mixture of Na₂O, B₂O₃, and SiO₂) substrate, a forsterite (Mg₂SiO₄) substrate, a lead glass (a mixture of Na₂O, PbO, and SiO₂) substrate, or an organic polymer substrate (for example, polymethyl methacrylate (polymethyl methacrylate: PMMA), polyvinyl alcohol (PVA), polyvinyl phenol (PVP), polyether sulfone (PES), polyimide, polycarbonate, polyethylene terephthalate (PET), or the like).

Furthermore, for example, the insulating layers 101 and 109 can be formed by a SiO₂-based material (for example, SiO₂, BPSG, PSG, BSG, AsSG, PbSG, SiON, SOG (spin on glass), low melting point glass, a glass paste, or the like), a SiN-based material, an insulating resin (for example, a polyimide resin, a novolac resin, an acrylic resin, polybenzoxazole, or the like), or the like, alone or in combination as appropriate.

It is sufficient that the organic layer 105 is configured to emit white light, and its specific configuration is not limited. For example, the organic layer 105 may be configured by a laminating structure of a hole transporting layer, a light emitting layer, and an electron transporting layer, a laminating structure of a hole transporting layer and a light emitting layer serving also as an electron transporting layer, a laminating structure of a hole injecting layer, a hole transporting layer, a light emitting layer, an electron transporting layer, and an electron injection layer, or the like. Furthermore, in a case where these laminating structures or the like are considered as “tandem units”, the organic layer 105 may have a two-stage tandem structure in which a first tandem unit, a connection layer, and a second tandem unit are laminated. Alternatively, the organic layer 105 may have a tandem structure of three or more stages in which three or more tandem units are laminated. In a case where the organic layer 105 includes a plurality of tandem units, the organic layer 105 that emits white light as a whole can be obtained by changing the emission color of the light emitting layer between red, green, and blue for each tandem unit.

Methods that can be used as a forming method of the organic layer 105 include, for example, a physical vapor deposition method (PVD method) such as the vacuum deposition method, a printing method such as the screen printing method and the inkjet printing method, a laser transfer method of irradiating a laminating structure of a laser absorption layer formed on a transfer substrate, and an organic layer with a laser beam to separate the organic layer on the laser absorption layer, and transferring the organic layer, or various coating methods.

Furthermore, for example, the first electrode 103 may be formed by a metal having a high work function such as platinum (Pt), gold (Au), silver (Ag), chromium (Cr), tungsten (W), nickel (Ni), copper (Cu), iron (Fe), cobalt (Co), or tantalum (Ta), or an alloy (for example, an Ag—Pd—Cu alloy containing silver as main component, and containing palladium (Pd) of 0.3 mass % to 1 mass %, and copper of 0.3 mass % to 1 mass %, or an Al—Nd alloy). Alternatively, as the first electrode 103, a conductive material having a small work function value and high light reflectance such as aluminum or an alloy containing aluminum can be used. In this case, it is preferable to improve the hole injectability by providing an appropriate hole injection layer on the first electrode 103, or the like. Alternatively, the first electrode 103 may have a structure in which a transparent conductive material having excellent hole injection characteristics such as indium and tin oxide (ITO), indium and zinc oxide (IZO), or the like is laminated on a dielectric multilayer film or a reflective film with high light reflectivity such as aluminum.

Furthermore, for example, the second electrode 107 can be formed by aluminum, silver, magnesium, calcium (Ca), sodium (Na), strontium (Sr), an alloy of alkali metal and silver, an alloy of alkali earth metal and silver (for example, an alloy of magnesium and silver (Mg—Ag alloy)), an alloy of magnesium and calcium (Mg—Ca alloy), an alloy of aluminum and lithium (Al—Li alloy), or the like. In a case where these materials are used in a single layer, the film thickness of the second electrode 107 is, for example, about 4 nm to 50 nm. Alternatively, the second electrode 107 may have a structure in which the above-described material layer and a transparent electrode (for example, about 30 nm to 1 μm in thickness) including, for example, ITO or IZO are laminated from the organic layer 105 side. In a case of such a laminating structure, the thickness of the above-mentioned material layer can also be reduced to, for example, about 1 nm to 4 nm. Alternatively, the second electrode 107 may include only a transparent electrode. Alternatively, a bus electrode (auxiliary electrode) including a low resistance material such as aluminum, an aluminum alloy, silver, a silver alloy, copper, a copper alloy, gold, or a gold alloy may be provided for the second electrode 107, so that the resistance is lowered in the entire second electrode 107.

Examples of a forming method of the first electrode 103 and the second electrode 107 include an evaporation method including the electron beam evaporation method, the hot filament evaporation method, and the vacuum evaporation method, the sputtering method, the chemical vapor deposition method (CVD method), the metal organic chemical vapor deposition (MOCVD) method, a combination of the ion plating method and the etching method, various printing methods (for example, the screen printing method, an ink jet printing method, the metal mask printing method, or the like), the plating method (an electroplating method, the electroless plating method, or the like), the lift-off method, the laser ablation method, the sol-gel method, and the like.

Returning to FIGS. 1 to 4, description of the manufacturing method will be continued. Once the light emitting element 110 is formed, next, a protective film 119 is laminated thereon (FIG. 2). In the first embodiment, the protective film 119 is formed by depositing SiN by the CVD method. In this manner, by forming the protective film 119 by the CVD method, as shown in the drawing, the convex shape of the convex portion 116 is so-called transferred to the upper surface of the protective film 119, and the upper surface of the protective film 119 has a substantially spherical convex shape corresponding to the convex shape of the convex portion 116.

Note that another vacuum deposition method such as the sputtering method, the vacuum deposition method, or the like may be used instead of the CVD method for forming the protective film 119. By forming the protective film 119 by the vacuum deposition method, the upper surface of the protective film 119 can be formed in a substantially spherical convex shape corresponding to the convex shape of the convex portion 116. Furthermore, the material of the protective film 119 is not limited to SiN, and other materials, for example, SiON may be used. However, as described later, in order to make the upper surface of the protective film 119 function as a condensing lens, it is preferable that a material having a relatively high refractive index (for example, a material having a refractive index of about 1.7 to about 2.0) be used as the material of the protective film 119. Note that the above-described refractive index of SiN is about 1.89.

Once the protective film 119 is formed, next, a planarizing film 121 is laminated thereon (FIG. 3). The planarization film 121 is formed by applying a resin material, a resist material, or the like used for white CF, for example. It is preferable that a material having a relatively low refractive index (for example, a material having a refractive index of about 1.4 to 1.6) be used as the material of the protective film 119. Specifically, as the material of the planarizing film 121, a material having a refractive index smaller than the refractive index of the protective film 119 is preferably used. By making the refractive index of the protective film 119 larger than the refractive index of the planarizing film 121 as described above, as shown in the drawing, the upper surface of the protective film 119 having a substantially spherical convex shape in the upward direction (in other words, the light emitting direction from the light emitting element 110) may function as a convex lens that condenses the light emitted from the light emitting element 110.

Note that, a material having a refractive index smaller than the refractive index of the protective film 119, as well as having almost the same refractive index as the CF layer 123 as described later may be used as the material of the protective film 119. As a result, reflection of light at the interface between the protective film 119 and the CF layer 123 is suppressed, and the light extraction efficiency can be further improved.

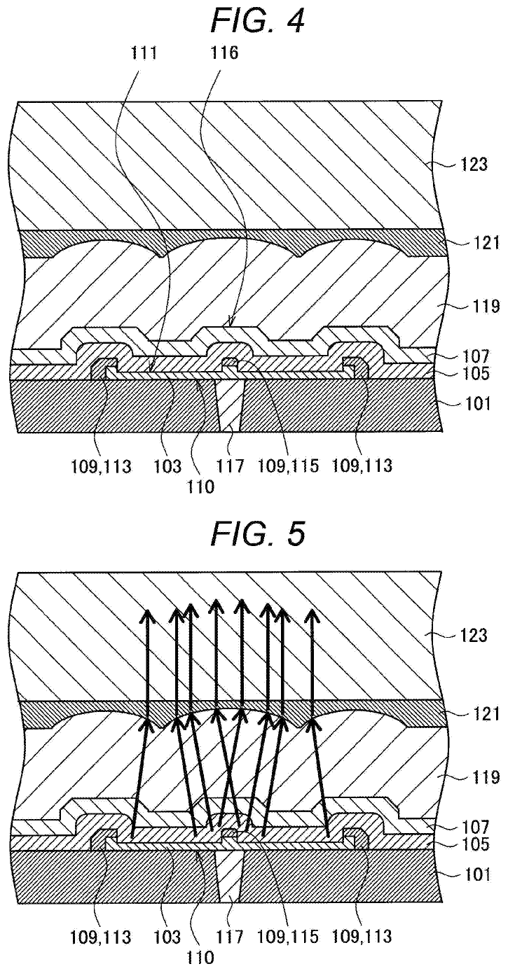

Once the planarizing film 121 is formed, next, the CF layer 123 is laminated thereon (FIG. 4). The CF layer 123 is formed so that the CF of each color having a predetermined area is provided for each light emitting element 110. As a material and a forming method of the CF layer 123, various known materials and methods used in a general organic EL display device may be used. For example, the CF layer 123 can be formed by exposing and developing a resist material in a predetermined shape by a photolithography technology. Furthermore, the arraying method of the CF in the CF layer 123 is not limited. For example, the arraying method may be various known arraying methods such as stripe arraying, delta arraying, or square arraying.

A second substrate (not shown) is bonded onto the CF layer 123 via a sealing resin film (not shown) so that the display device according to the first embodiment is prepared. Note that the material of the sealing resin film may be selected as appropriate with consideration that transparency to light emitted from the light emitting element 110 is high, adhesion to the CF layer 123 located in the lower layer and the second substrate located in the upper layer is excellent, the reflectivity of light in an interface with the CF layer 123 located in the lower layer and an interface with the second substrate located in the upper layer is low, and the like. Furthermore, a similar material to that of the first substrate can be used as the material of the second substrate. However, since the display device according to the first embodiment is a top emission type, a material that can suitably transmit light from the light emitting element 110 is used as the material of the second substrate.

The manufacturing method of the display device according to the first embodiment has been described above. As described above, in the first embodiment, when the opening 111 with respect to the first electrode 103 for defining the light emitting region of the light emitting element 110 is formed in the insulating layer 109, the insulating layer 109 remains in a partial region in the opening 111. As a result, the light emitting element 110 has the convex portion 116 protruding upward from the other regions, in a partial region of the light emitting region. Accordingly, when the protective film 119 is laminated on the light emitting element 110, a substantially spherical convex shape corresponding to the shape of the convex portion 116 is formed in the region corresponding to right above the light emitting element 110 on the upper surface of the protective film 119.

At this time, since the materials of the protective film 119 and the planarizing film 121 may be selected such that the refractive index of the protective film 119 is larger than the refractive index of the planarizing film 121, as shown in FIG. 5, the convex shape of the upper surface of the protective film 119 functions as a convex lens for condensing the light emitted from the light emitting element 110. That is, the ML is formed right above the light emitting element 110 so that the light extraction efficiency can be improved. FIG. 5 is a view for describing an effect of the ML in the display device according to the first embodiment. FIG. 5 schematically shows, with respect to the display device shown in FIG. 4, a state in which the light emitted from the light emitting element 110 is condensed by the upper surface (in other words, the ML) of the protective film 119, passes through the CF layer 123, and is extracted outward, by arrows (description of some reference numerals is omitted for avoiding complication of the drawing).

In this manner, in the first embodiment, the ML may be formed by so-called transferring the shape of the convex portion 116 formed in a partial region of the light emitting region onto the upper surface of the protective film 119. That is, since the ML is formed in a self-aligning manner with respect to the light emitting element 110, so that it is possible to accurately perform the alignment between the light emitting element 110 and the ML. Here, although the convex portion 116 is formed according to the remaining film 115, the step of forming the remaining film 115 is the same step as the step of forming the pixel definition film 113. That is, in the step of defining the opening 111, that is, the light emitting region of the light emitting element 110, the remaining film 115 is formed. Accordingly, the position of the ML formed on the basis of the remaining film 115 is also determined in the step of defining this light emitting region. Therefore, in the first embodiment, it is possible to keep the positional accuracy of the ML with respect to the light emitting region extremely high.

Here, in the method disclosed in Patent Document 1, similarly, the ML may be formed in a self-aligning manner, but the entire light emitting region of the light emitting element is formed on the curved surface. Accordingly, as described above, it is difficult to form the organic layer with a uniform thickness, and there is a concern that variations in characteristics among the light emitting elements are large. On the other hand, in the first embodiment, as described above, the convex portion is formed in a partial region of the light emitting region, so that the ML is formed in a self-aligning manner. Since the other region of the light emitting region is substantially flat, it is easy to form the organic layer 105 with substantially uniform thickness at least in the other region. Therefore, it is possible to improve the accuracy of the alignment between the light emitting element 110 and the ML while suppressing occurrence of variations in characteristics among the light emitting elements 110.

Furthermore, in the method disclosed in Patent Document 1, it is difficult to miniaturize the pixel pitch, since the convex portion is formed so as to have an area larger than the light emitting region of the light emitting element. On the other hand, in the first embodiment, as described above, the convex portion is formed in a partial region of the light emitting region of the light emitting element 110. Accordingly, it is possible to cope with miniaturization of the pixel pitch. As described above, the manufacturing method of the display device according to the first embodiment can be suitably applied to an ultra-compact display device. By manufacturing an ultra-compact display device by the manufacturing method according to the first embodiment described above, even in a case where the pixel pitch is miniaturized, alignment between the light emitting element 110 and the ML can be accurately performed. Therefore, it is possible to realize high-definition display without causing problems (degradation of optical characteristics such as luminance, chromaticity, viewing angle characteristics, or the like) due to the reduction of the alignment accuracy. Therefore, a high quality display device can be realized.

Furthermore, the step of laminating the protective film 119 and the planarizing film 121 on the light emitting element 110 is a step that is also performed in a general organic EL display device. Furthermore, the formation of the remaining film 115 in the opening 111 can also be realized by changing the patterning at the time of etching the insulating layer 109. As described above, in the first embodiment, the ML can be formed without adding a new step or greatly changing the existing steps with respect to a general manufacturing method of an organic EL display device. Therefore, it is possible to manufacture a display device substantially without increasing the manufacturing cost as compared with the existing method.

(2-2. Configuration of Main Part of Display Device)

The configuration of the main part of the display device according to the first embodiment will be described. Note that, here, as an example, the configuration of the main part in a case where the display device is an ultra-compact display device will be described.

(2-2-1. Shape of Cross Section)

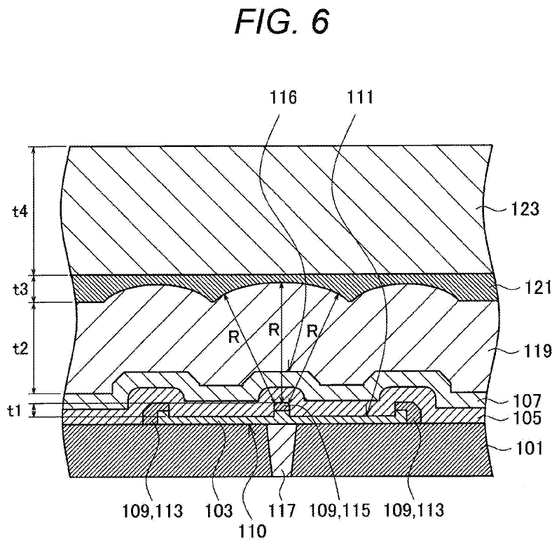

FIG. 6 is a view for describing a cross-sectional shape of a main part of the display device according to the first embodiment. In FIG. 6, the film thickness or the like of each layer is additionally described with respect to FIG. 4.

For example, in the first embodiment, the height t1 of the convex shape formed by the remaining film 115 from the surface of the first electrode 103 (conveniently referred to as the thickness t1 of the remaining film 115) may be about 0.2 μm to about 0.5 μm. Furthermore, the thickness t2 of the protective film 119 laminated may be about 0.5 μm to about 2.5 μm.

The thickness t1 of the remaining film 115 and the thickness t2 of the protective film 119 may be factors with which the curvature radius R of the finally formed ML (in the first embodiment, defined as the distance from the surface of the remaining film 115 to the upper surface of the convex shaped protective film 119) can be determined. Accordingly, in the first embodiment, the thickness t1 of the remaining film 115 and the thickness t2 of the protective film 119 may be appropriately determined so as to obtain a desired curvature radius R that can effectively improve the light extraction efficiency. For example, the thickness t1 of the remaining film 115 and the thickness t2 of the protective film 119 can be appropriately determined within the above-described range so that the curvature radius R of the ML is about 0.5 μm to about 3.0 μm. Note that the specific value of the desired curvature radius R that can effectively improve the light extraction efficiency may be calculated as appropriate on the basis of simulation, experiment, or the like. Furthermore, the relationship among the curvature radius R of the ML, the thickness t1 of the remaining film 115, and the thickness t2 of the protective film 119 may be appropriately predicted on the basis of simulation, experiment, or the like, and the thickness t1 of the remaining film 115 and the thickness t2 of the protective film 119 with which a desired curvature radius R can be obtained may be appropriately determined on the basis of the relationship.

The thickness t3 of the planarizing film 121 can be appropriately determined so that the surface is reliably flat, and the emitted light from the light emitting element 110 is not attenuated as much as possible. For example, the thickness t3 of the planarizing film 121 may be about 0.1 μm to about 1.0 μm.

The thickness t4 of the CF layer 123 may be appropriately determined so that a desired chromaticity can be obtained and the emitted light from the light emitting element 110 is not attenuated as much as possible. For example, the thickness t4 of the CF layer 123 may be about 0.5 μm to about 2.0 μm.

(2-2-2. Shape of Plane)

FIG. 7 is a view for describing dimensions of a shape in a horizontal surface of the main part of the display device according to the first embodiment. FIG. 7 schematically shows the structure of the main part of the display device according to the first embodiment in the horizontal plane, and also shows the structure of the cross section in the configuration corresponding to one pixel, showing the correspondence between the two structures.

FIG. 7 schematically shows the planar layout of the opening 111 and the insulating layer 109 in each pixel as a main part of the display device. For explanation, the insulating layer 109 (the pixel definition film 113 and the remaining film 115) is hatched with the same hatching as the insulating layer 109 in FIGS. 1 to 4.

FIG. 7 shows, as an example, the planar layout in a case where the arraying of the CF is the delta arraying. In a case of the delta arraying, as shown in the drawing, a regular hexagonal opening 111 is formed by the pixel definition film 113 (that is, a regular hexagonal pixel is formed). The width d1 of the opening 111 in the horizontal plane (in other words, the width d1 of the light emitting region) may be, for example, about 0.5 μm to about 10 μm. A specific value of the width d1 of the light emitting region may be appropriately determined on the basis of specifications such as the panel size and the number of pixels of the display device.

The shape of the remaining film 115 in a case of being viewed from above may be substantially circular. Furthermore, the width d2 of the remaining film 115 in the horizontal plane may be a factor with which the curvature radius R of the finally formed ML may be determined. Accordingly, the width d2 of the remaining film 115 may be appropriately determined so as to obtain a desired curvature radius R that can effectively improve the light extraction efficiency. For example, the width d2 of the remaining film 115 with which the above-described curvature radius R (about 0.5 μm to about 3.0 μm) is realized may be about 0.15 μm to about 2 μm. Note that the relationship between the curvature radius R of the ML and the width d2 of the remaining film 115 may be appropriately predicted on the basis of simulation, experiment, or the like, and the width d2 of the remaining film 115 with which a desired curvature radius R can be obtained may be appropriately determined on the basis of the relationship.

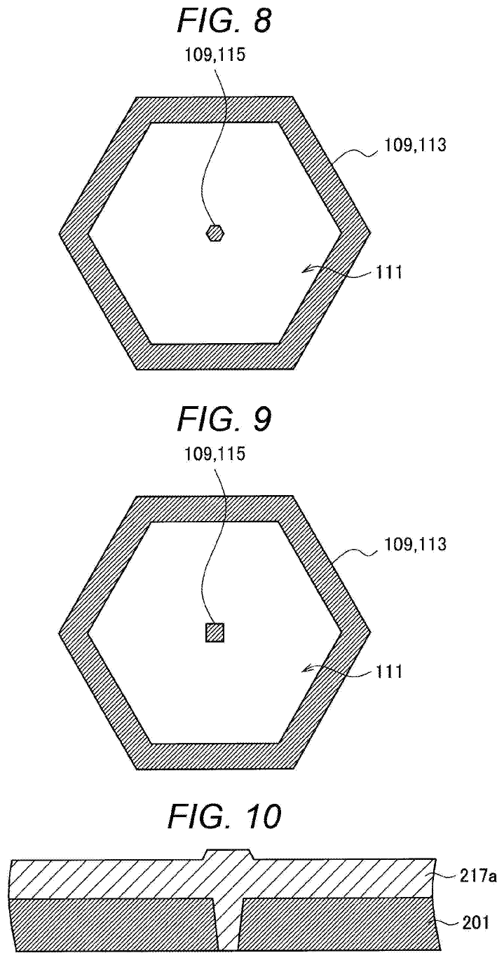

Note that, in the above-described configuration example, the shape of the remaining film 115 in a case of being viewed from above is substantially circular, but the present embodiment is not limited to this example. The shape of the remaining film 115 may be arbitrary, for example, a polygonal shape, or the like. FIGS. 8 and 9 are views showing another examples of the shape of the remaining film 115 in a case of being viewed from above. For example, as shown in FIG. 8, the shape of the remaining film 115 may be a regular hexagon. Alternatively, as shown in FIG. 9, the shape of the remaining film 115 may be a square shape. As described above, even in a case where the shape of the remaining film 115 in a case of being viewed from above is changed, a substantially spherical convex shape corresponding to the convex shape may be similarly formed on the upper surface of the protective film 119, so that the ML can be formed.

### 3. Second Embodiment

A second embodiment of the present disclosure will be described. In the first embodiment described above, when the pixel definition film 113 is formed, the insulating layer 109 remains in the opening 111, so that the convex shape is formed in a partial region of a region corresponding to the light emitting region of the first electrode 103. However, the present disclosure is not limited to such an example. As long as the convex shape is formed in a partial region of the region corresponding to the light emitting region of the first electrode 103, the convex portion 116 is formed in the partial region of the light emitting region of the light emitting element 110 by the convex shape, and a substantially spherical convex shape corresponding to the convex shape of the convex portion 116 can be formed on the upper surface of the protective film 119 (in other words, the ML can be formed), so that a forming method of a convex shape in the first electrode 103 may be another method. Here, as the second embodiment, an embodiment in which such a convex shape of the first electrode 103 is formed by another method will be described. Note that, in the second embodiment, only the method of forming the convex shape of the first electrode 103 is different from the first embodiment, and other configurations of the display device may be similar to those of the first embodiment.

The manufacturing method of the display device according to the second embodiment will be described with reference to FIGS. 10 to 16. FIGS. 10 to 16 are views for describing the manufacturing method of the display device according to the second embodiment. FIGS. 10 to 16 schematically show a cross section parallel to the vertical direction of the display device according to the second embodiment in the order of steps in the manufacturing method of the display device, and represent the process flow in the manufacturing method. Note that, in FIGS. 10 to 16, in order to describe characteristic steps of the manufacturing method, only a part of the structure related to these steps in the display devices is described.

In the manufacturing method of the display device according to the second embodiment, as similar to the manufacturing method according to the first embodiment, first, a driving circuit (not shown) for driving the light emitting element 210 as described later is formed on a first substrate (not shown). Then, the insulating layer 201 is laminated on the driving circuit formed. A via 217 for electrically connecting the driving circuit and the light emitting element 210 is formed in the insulating layer 201. Note that the first substrate, the driving circuit, and the insulating layer 201 may be similar to the first substrate, the driving circuit, and the insulating layer 101 according to the first embodiment.

Here, in the second embodiment, the forming method of the via 217 is different from that of the first embodiment. Hereinafter, referring to FIGS. 10 to 12, the forming method of the via 217 will be specifically described.

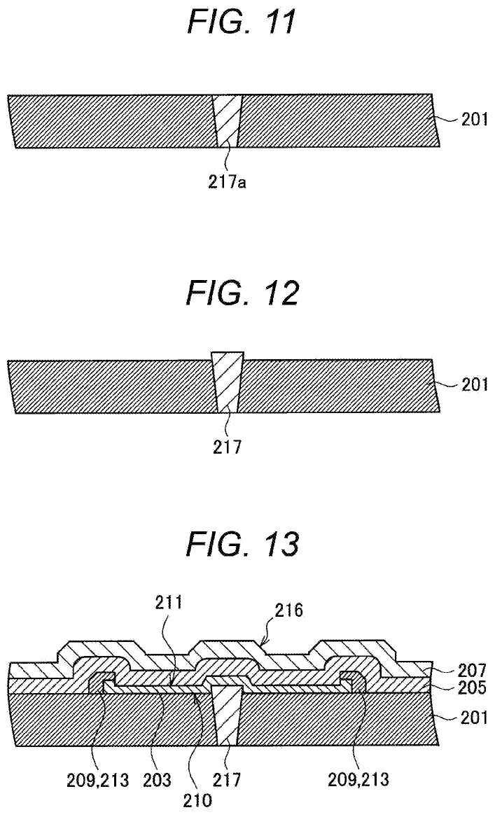

In the forming method of the via 217, first, an opening is provided in the insulating layer 201, for example, by the dry etching method, and then, a conductive material 217a such as W is embedded in the opening by the sputtering method (FIG. 10). Next, the surfaces of the insulating layer 201 and the embedded conductive material 217a are planarized by the CMP (FIG. 11). Then, the via 217 is formed by etching the insulating layer 201 by etching back (FIG. 12).

In the first embodiment, the via 117 is formed by similar steps to the steps shown in FIGS. 10 and 11. Accordingly, the upper end of the via 117 has substantially the same height as the surface of the insulating layer 101, and no step is generated on the surface of the insulating layer 101. On the other hand, in the second embodiment, the via 217 is formed by the above-described method, so that the upper end of the via 217 protrudes above the surface of the insulating layer 201. That is, a convex shape due to the via 217 exists on the surface of the insulating layer 201.

In the second embodiment, in this state, the light emitting element 210 including an organic EL element is formed on the insulating layer 201 (FIG. 13). The forming method of the light emitting element 210 is similar to the forming method of the light emitting element 110 according to the first embodiment. Specifically, the light emitting element 210 includes the first electrode 203 that functions as an anode, the organic layer 205 including an organic light emitting material that functions as a light emitting layer, and a second electrode 207 that functions as a cathode, laminated in this order.

More specifically, the first electrode 203 is formed on the insulating layer 201. An insulating layer 209 provided with an opening 211 such that at least a part of the first electrode 203 is exposed is laminated on the first electrode 203, and the organic layer 205 and the second electrode 207 are laminated on the first electrode 203 and the insulating layer 209 so as to contact the first electrode 203 exposed at the bottom portion of the opening 211. That is, the light emitting element 210 has a structure in which the first electrode 203, the organic layer 205, and the second electrode 207 are laminated in this order in the opening 211 of the insulating layer 209. A region corresponding to the opening 211 of the insulating layer 209 of the light emitting element 210 corresponds to the light emitting region of the light emitting element 210. Note that the insulating layer 209, the first electrode 203, the organic layer 205, and the second electrode 207 may be similar to the insulating layer 109, the first electrode 103, the organic layer 105, and the second electrode 107 according to the first embodiment.

One light emitting element 210 constitutes one pixel. In FIGS. 10 to 16, only a region corresponding to one light emitting element 210 is shown, but in reality, a plurality of light emitting elements 210 are arrayed in a region corresponding to a display region on a first substrate two-dimensionally at predetermined pixel pitches. Furthermore, the insulating layer 209 described above functions as the pixel definition film 213.

In the second embodiment, since the upper end of the via 217 protrudes from the surface of the insulating layer 201, when the first electrode 203 is laminated thereon, a convex shape corresponding to the protruding shape by the via 217 is formed in the first electrode 203. When the organic layer 205 and the second electrode 207 are further laminated thereon, the organic layer 205 and the second electrode 207 also have a convex shape corresponding to the protruding shape by the via 217. In other words, the protruding shape by the via 217 is transferred to the shapes of the first electrode 203, the organic layer 205, and the second electrode 207. Therefore, as shown in the drawing, the light emitting element 210 has a convex portion 216 protruding upward from the other regions, in a partial region of the light emitting region. That is, the light emitting element 210 has a configuration in which the convex portion 216 exists in a partial region in the substantially flat light emitting region. In the illustrated configuration example, one via 217 is provided substantially at the center in the horizontal plane of the light emitting region, and correspondingly, one convex portion 216 is provided substantially at the center in the horizontal plane of the light emitting region.

Note that, in the first embodiment, when the opening 111 is provided in the insulating layer 109, the insulating layer 109 remains in a partial region in the opening 111 so that the remaining film 115 is formed. Then, the convex portion 116 is formed by the remaining film 115. On the other hand, in the second embodiment, as described above, since the convex portion 216 is formed by the via 217, it is not necessary to make the insulating layer 209 remain in the opening 211. Accordingly, in the second embodiment, when the opening 211 is formed, only the pixel definition film 213 is formed without making the insulating layer 209 remain in the opening 211.

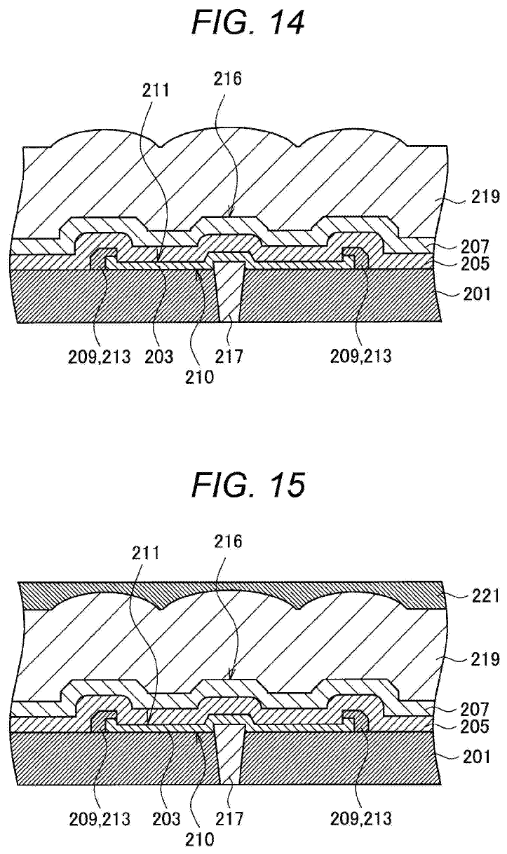

The subsequent steps are similar to those in the first embodiment. Specifically, once the light emitting element 210 is formed, next, a protective film 219 is laminated thereon (FIG. 14). The protective film 219 is similar to the protective film 119 according to the first embodiment. For example, the protective film 219 is formed by depositing SiN by the CVD method. As a result, as shown in the drawing, the convex shape of the convex portion 216 is so-called transferred to the upper surface of the protective film 219, and the upper surface of the protective film 219 has a substantially spherical convex shape corresponding to the convex shape of the convex portion 216.

Once the protective film 219 is formed, next, a planarizing film 221 is laminated thereon (FIG. 15). The planarizing film 221 is similar to the planarizing film 121 according to the first embodiment. For example, the planarizing film 221 is formed including a resin material having a refractive index lower than that of the protective film 219. As a result, the substantially spherical convex shape of the upper surface of the protective film 219 can function as a convex lens that condenses the light emitted from the light emitting element 110.

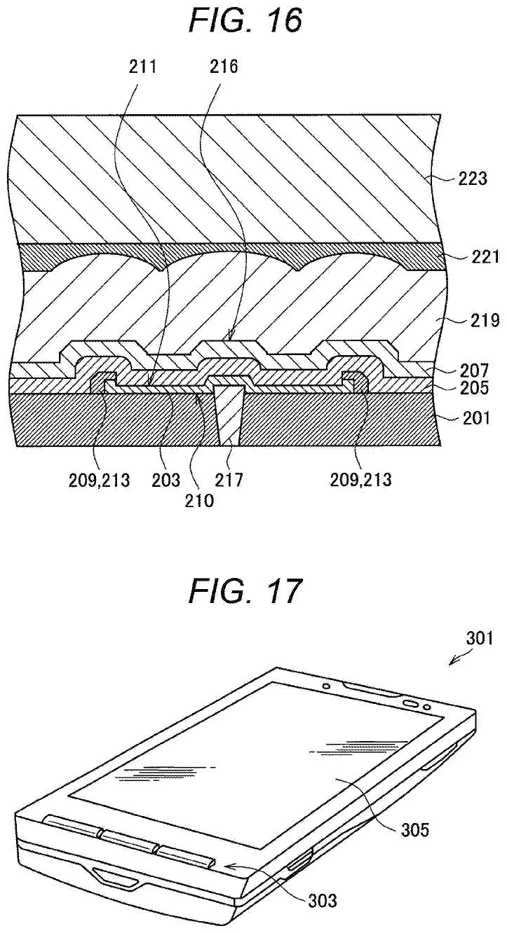

Once the planarizing film 221 is formed, next, the CF layer 223 is laminated thereon (FIG. 16). Then, a second substrate (not shown) is bonded onto the CF layer 223 via a sealing resin film (not shown) so that the display device according to the second embodiment is prepared. Note that the CF layer 223, the sealing resin film, and the second substrate may be similar to the CF layer 123, the sealing resin film, and the second substrate according to the first embodiment.

The manufacturing method of the display device according to the second embodiment has been described above. As described above, in the second embodiment, in forming the via 217 for electrically connecting the first electrode 203, that is the lower layer electrode constituting the light emitting element 210, to the lower layer driving circuit, the upper end of the via 217 protrudes from the surface of the insulating layer 201 on which the via 217 is provided. As a result, as a result, the light emitting element 210 has the convex portion 216 protruding upward from the other regions, in a partial region of the light emitting region. Accordingly, when the protective film 219 is laminated on the light emitting element 210, a substantially spherical convex shape corresponding to the shape of the convex portion 216 is formed in the region corresponding to the right above the light emitting element 210 on the upper surface of the protective film 219. At this time, since the materials of the protective film 219 and the planarizing film 221 may be selected such that the refractive index of the protective film 219 is larger than the refractive index of the planarizing film 221, the convex shape of the upper surface of the protective film 219 functions as a convex lens for condensing the light emitted from the light emitting element 210. That is, the ML is formed right above the light emitting element 210.

As described above, according to the second embodiment, as similar to the first embodiment, it is possible to form the ML right above each light emitting element 210 in a self-aligning manner. Accordingly, it is possible to obtain similar effects to those in the first embodiment (that is, the light extraction efficiency can be improved, the accuracy of the alignment between the light emitting element 210 and the ML can be improved without causing variations in characteristics of each light emitting element 210, the accuracy of the alignment can be kept high even in a case where the pixel pitch is miniaturized, an increase in manufacturing costs can be suppressed, or the like).

Note that, as described above, in the first embodiment, the convex portion 116 is formed by forming the remaining film 115 in a partial region of the light emitting region of the light emitting element 110. In this configuration, since the portion where the remaining film 115 exists does not emit light, there is a concern that the luminance of the light emitting element 110 may decrease. On the other hand, in the second embodiment, since the remaining film 115 is not formed in the light emitting region of the light emitting element 210, the entire light emitting region contributes to light emission. Therefore, as compared to the first embodiment, it is possible to obtain an effect of improving luminance. Note that, also in the first embodiment, since the ML is formed by providing the convex portion 116, the effect of improving the luminance by the ML is obtained, so that the influence of the reduction in luminance due to the remaining film 115 may be canceled. Accordingly, also in the first embodiment, it is considered that the effect of luminance improvement can be sufficiently obtained as compared with the structure in which the ML is not provided.

### 4. Application Example

Application examples of the display device according to each embodiment described above will be described. Here, some examples of electronic devices to which the display device according to each embodiment described above can be applied will be described.

FIG. 17 is a view showing an appearance of a smartphone which is an example of an electronic device to which the display device according to each embodiment can be applied. As shown in FIG. 17, a smartphone 301 has an operation unit 303 that includes buttons and receives operation input by a user, and a display unit 305 that displays various kinds of information. In a case where the display device according to each embodiment is a compact or medium display device, the display device may be suitably applied to the display unit 305.

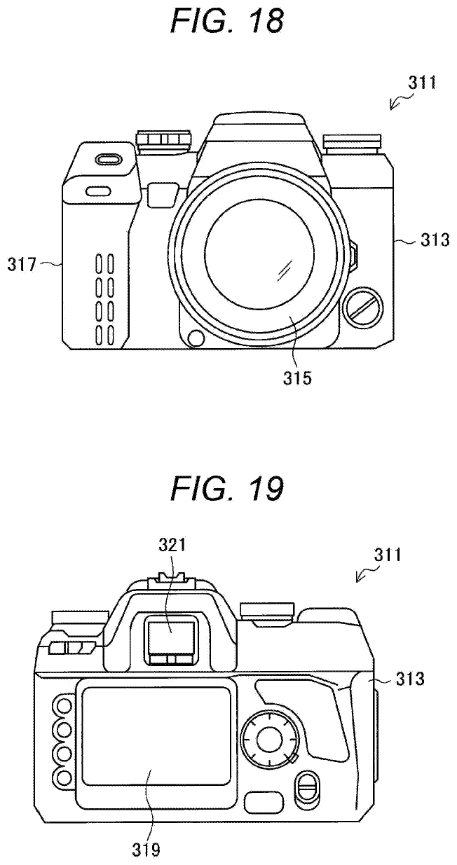

FIGS. 18 and 19 are views showing an appearance of a digital camera which is another example of an electronic device to which the display device according to each embodiment can be applied. FIG. 18 shows an appearance of a digital camera 311 viewed from the front (subject side), and FIG. 19 shows an appearance of the digital camera 311 viewed from the rear. As shown in FIGS. 18 and 19, the digital camera 311 includes a main body unit (camera body) 313, an interchangeable lens unit 315, a grip unit 317 gripped by a user at the time of photographing, a monitor 319 that displays various kinds of information, and an EVF 321 that displays a through image to be observed by the user at the time of photographing. In a case where the display device according to each embodiment is a compact or medium display device, the display device may be suitably applied to the monitor 319. In a case where the display device according to each embodiment is an ultra-compact display device, the display device may be suitably applied to the EVF 321.

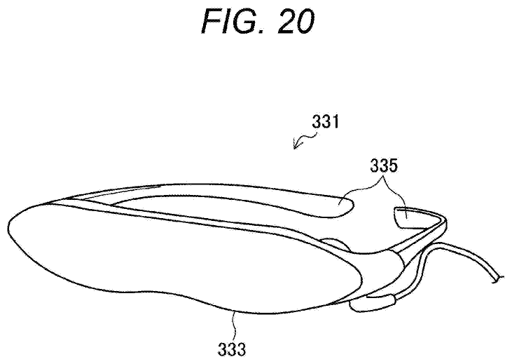

FIG. 20 is a view showing an appearance of an HMD which is another example of an electronic device to which the display device according to each embodiment can be applied. As shown in FIG. 20, the HMD 331 has a glasses-shaped display unit 333 that displays various kinds of information, and an ear hook unit 335 to be hooked to the user's ear when attached. In a case where the display device according to each embodiment is an ultra-compact display device, the display device may be suitably applied to the display unit 333.

Several examples of electronic devices to which the display device according to each embodiment can be applied have been described above. Note that electronic devices to which the display device according to each embodiment can be applied are not limited to those exemplified above, and the display device can be applied to a display device mounted to an electronic device of any fields that performs display on the basis of an image signal input from the outside such as a television device, a tablet PC, an electronic book, a personal digital assistant (PDA), a notebook PC, a video camera, or a game machine, or an image signal internally generated, according to the size of the display device.

### 5. Supplement

While preferred embodiments of the present disclosure have been described above in detail with reference to the accompanying drawings, the technical scope of the present disclosure is not limited to such examples. It is obvious that various variations and modifications can be conceived within the scope of the technical idea described in the claims by a person having ordinary knowledge in the field of technology to which the present disclosure belongs, and, of course, it is understood that these variations and modifications belong to the technical scope of present disclosure.

For example, in the above embodiment, the convex portion 116 or 216 is formed substantially at the center in the horizontal plane of the light emitting region, but the present technology is not limited to this example. The position where the convex portion 116 or 216 is formed may be arbitrary positions in the light emitting region. However, since the position of the center of the convex shape of the upper surface of the protective film 119 or 219 in the horizontal plane (in other words, the position of the ML in the horizontal plane) may also change according to the position of the convex portion 116 or 216 in the horizontal plane, the positions of the convex portion 116 or 216 may be appropriately determined so that the ML can be formed at a desired position in consideration of characteristics or the like of the light emitting element 110 or 210.

Furthermore, in the above embodiment, only one convex portion 116 or 216 is formed in the light emitting region, but the present disclosure is not limited to this example. A plurality of convex portions 116 or 216 may be formed in the light emitting region. In a case where a plurality of convex portions 116 or 216 are formed in the light emitting region, the convex shape is formed on the upper surface of the protective film 119 or 219 according to the convex portion 116 or 216, so that a plurality of MLs are formed for one light emitting element 110 or 210. Depending on the characteristics of the light emitting element 110 or 210, there is a possibility that it is possible to more effectively improve the light extraction efficiency when a plurality of MLs are formed for one light emitting element 110 or 210. Therefore, in such a case, the position and shape of the convex portion 116 or 216 formed in the light emitting region may be appropriately determined so that a desired number of MLs may be formed at desired positions.

Furthermore, in the above embodiment, the CF is provided on the upper layer of the protective film 119 or 219, but the present disclosure is not limited to this example. For example, in a case where the display device is of a method in which light of each color of RGB is emitted by a light emitting element (so-called RGB color method) or in a case where the display device is configured to be capable of monochrome display, the CF may not be provided.

Furthermore, in the above embodiment, used as a method for forming the convex portion 116 or 216, are a method of making the insulating layer 109 remain when forming the pixel definition film 113 to form the convex shape on the first electrode 103 or 203 in the opening 111 or 211, and a method of making the upper end of the via 217 protrude from the surface of the insulating layer 201 when forming the via 217 to form the convex shape on the first electrode 103 or 203 in the opening 111 or 211, but the present disclosure is not limited to this example. When the convex shape is formed on the first electrode 103 or 203 in the opening 111 or 211, depending on the convex shape, convex shapes are formed also in the organic layer 105 or 205 and the second electrode 107 or 207 laminated on the first electrode 103 or 203, and a convex portion similar to the convex portion 116 or 216 can be formed. Therefore, a method of forming the convex shape with respect to the first electrode 103 or 203 may be arbitrary.

Furthermore, in the present disclosure, at least when the light emitting element 110 or 210 is formed, if a convex portion is formed at a portion corresponding to the light emitting region of the light emitting element 110 or 210 of the second electrode 107 or 207 that is an upper layer electrode of the light emitting element 110 or 210, a convex shape may also be formed on the upper surface of the protective film 119 or 219 laminated on the light emitting element 110 or 210 according to the shape of the convex portion (in other words, the ML may be formed). The method for forming such a convex portion is not limited to the method of providing a convex shape on the first electrode 103 or 203, and may be arbitrary, or may be a method other than the above-described embodiments. For example, in the region corresponding to the light emitting region, the first electrode 103 or 203 and the organic layer 105 or 205 are formed flat, and the shape of the second electrode 107 or 207 may be processed so that a convex portion may be locally provided only on the upper surface of the second electrode 107 or 207.

Furthermore, in the above embodiment, the protective film 119 or 219 is laminated right above the light emitting element 110 or 210, and the planarizing film 121 or 221 is laminated right above the protective film 119 or 219. However, the present disclosure is not limited to this example. Depending on the configuration of the display device, films having different functions and names may be laminated right above and further right above the light emitting element 110 or 210. In the technology according to the present disclosure, the types of the first film and the second film are not limited as long as the first film laminated right above the light emitting element 110 or 210 is formed by a material having a similar refractive index to that of the protective film 119 or 219 in the above embodiment and a method similar to that in the above embodiment, and the second film laminated right above the first film is formed by a material having a similar refractive index to that of the planarizing film 121 or 221 in the above embodiment.

Note that the technology according to the present disclosure can provide the effect when the ML is formed by the method corresponding to the above-described embodiment, and the other configuration of the display device may be arbitrary. In other words, the forming method of the ML according to the present disclosure may be applied to a display device having an arbitrary configuration as far as possible.

Furthermore, the effects described in this specification are merely descriptive or illustrative and are not limiting. That is, the technology according to the present disclosure can exhibit other effects obvious to those skilled in the art from the description of this specification together with the above-described effects or instead of the above-described effects.

Note that the following configuration is also within the technical scope of the present disclosure.

(1)

A display device including:

a plurality of light emitting elements formed on a substrate; and

a first film laminated on the plurality of light emitting elements,

in which a convex portion protruding upward exists in a partial region of a light emitting region of the light emitting elements, and

an upper surface of the first film has a substantially spherical convex shape corresponding to the convex portion.

(2)

The display device according to (1) above,

in which a second film formed by a material having a smaller refractive index than a refractive index of the first film is laminated right above the first film.

(3)

The display device according to (1) or (2) above,

in which the light emitting region is a plain surface except for a region where the convex portion is provided.

(4)

The display device according to any one of (1) to (3) above,

in which the convex portion includes at least an insulator that is the same as a pixel definition film that defines an area of the light emitting region.

(5)

The display device according to any one of (1) to (3) above,

in which a via that electrically connects a lower layer electrode of the light emitting element and a further lower layer circuit exists in a lower layer of the convex portion.

(6)

The display device according to any one of (1) to (5) above

in which a color filter layer exists in an upper layer of the first film.

(7)

The display device according to any one of (1) to (6) above,

in which the only one convex portion exists in the light emitting region of one of the light emitting elements.

(8)

The display device according to any one of (1) to (6) above,

in which a plurality of the convex portions exists in the light emitting region of one of the light emitting elements.

(9)

The display device according to any one of (1) to (8) above,

in which a shape of the convex portion in a case of being viewed from above is substantially circular.

(10)

The display device according to (9) above

in which a diameter of the convex portion that is substantially circular in a case of being viewed from above is about 0.15 μm to about 2.0 μm.

(11)

The display device according to any one of (1) to (8) above,

in which a shape of the convex portion in a case of being viewed from above is polygon.

(12)

The display device according to any one of (1) to (11) above

in which the display device is an organic EL display device.

(13)

An electronic device including

a display device that performs display on the basis of an image signal,

the display device including a plurality of light emitting elements formed on a substrate, and

a first film laminated on the plurality of light emitting elements,

in which a convex portion protruding upward exists in a partial region of a light emitting region of the light emitting elements, and

an upper surface of the first film has a substantially spherical convex shape corresponding to the convex portion.

(14)

A manufacturing method of a display device, including:

a step of forming a plurality of light emitting elements on a substrate; and

a step of laminating a first film on the plurality of light emitting elements,

in which a convex portion protruding upward is formed in a partial region of a light emitting region of the light emitting elements, and

in the step of laminating the first film, the first film is laminated on the convex portion so that an upper surface of the first film has a substantially spherical convex shape corresponding to the convex portion.

(15)

The manufacturing method of a display device according to (14) above,

in which the first film is laminated by a vacuum film forming method.

(16)

The manufacturing method of a display device according to (14) or (15) above, further including

a step of laminating a second film formed by a material having a smaller refractive index than a refractive index of the first film right above the first film.

(17)

The manufacturing method of a display device according to any one of (14) to (16) above,

in which the step of forming the plurality of light emitting elements includes a step of forming a lower layer electrode of the light emitting elements, a step of laminating an insulating layer on the lower layer electrode, and a step of patterning the insulating layer so as to expose a region corresponding to the light emitting region of a surface of the lower layer electrode to form a pixel definition film that defines an area of the light emitting region,

in the step of forming the pixel definition film, the insulating layer is patterned such that the insulating layer remains in a partial region of a region corresponding to the light emitting region of the surface of the lower layer electrode, and

the convex portion is formed by laminating an organic layer and an upper layer electrode of the light emitting elements on the insulating layer that remains.

(18)

The manufacturing method of a display device according to any one of (14) to (16) above, further including

a step of forming a via electrically connecting a lower layer electrode and a further lower layer circuit of the light emitting elements before the step of forming the plurality of light emitting elements,

in which, in the step of forming the via, the via is formed such that an upper end of the via protrudes above a surface of the insulating layer on which the via is formed, and

the convex portion is formed by laminating the lower layer electrode, the organic layer, and the upper layer electrode of the light emitting elements on the via protruding from the surface of the insulating layer.

### REFERENCE SIGNS LIST

101, 201 Insulating layer
103, 203 First electrode
105, 205 Organic layer
107, 207 Second electrode
109, 209 Insulating layer
110, 210 Light emitting element
111, 211 Opening
113, 213 Pixel definition film
115 Remaining film
116, 216 Convex portion
117, 217 Via
119, 219 Protective film
121, 221 Planarizing film
123, 223 CF layer
217a Conductive material
301 Smartphone (electronic device)
311 Digital camera (electronic device)
331 HMD (electronic device)

1. A display device comprising:
a plurality of light emitting elements formed on a substrate; and
a first film laminated on the plurality of light emitting elements,
wherein a convex portion protruding upward exists in a partial region of a light emitting region of the light emitting elements, and
an upper surface of the first film has a substantially spherical convex shape corresponding to the convex portion.

2. The display device according to claim 1,
wherein a second film formed by a material having a smaller refractive index than a refractive index of the first film is laminated right above the first film.

3. The display device according to claim 1,
wherein the light emitting region is a plain surface except for a region where the convex portion is provided.

4. The display device according to claim 1,
wherein the convex portion includes at least an insulator that is the same as a pixel definition film that defines an area of the light emitting region.

5. The display device according to claim 1,
wherein a via that electrically connects a lower layer electrode of the light emitting element and a further lower layer circuit exists in a lower layer of the convex portion.

6. The display device according to claim 1,
wherein a color filter layer exists in an upper layer of the first film.

7. The display device according to claim 1,
wherein the only one convex portion exists in the light emitting region of one of the light emitting elements.

8. The display device according to claim 1,
wherein a plurality of the convex portions exists in the light emitting region of one of the light emitting elements.

9. The display device according to claim 1,
wherein a shape of the convex portion in a case of being viewed from above is substantially circular.

10. The display device according to claim 9,
wherein a diameter of the convex portion that is substantially circular in a case of being viewed from above is about 0.15 μm to about 2.0 μm.

11. The display device according to claim 1,
wherein a shape of the convex portion in a case of being viewed from above is polygon.

12. The display device according to claim 1,
wherein the display device is an organic EL display device.

13. An electronic device comprising
a display device that performs display on a basis of an image signal,
the display device including a plurality of light emitting elements formed on a substrate, and
a first film laminated on the plurality of light emitting elements,
wherein a convex portion protruding upward exists in a partial region of a light emitting region of the light emitting elements, and
an upper surface of the first film has a substantially spherical convex shape corresponding to the convex portion.

14. A manufacturing method of a display device, comprising:
a step of forming a plurality of light emitting elements on a substrate; and
a step of laminating a first film on the plurality of light emitting elements,
wherein a convex portion protruding upward is formed in a partial region of a light emitting region of the light emitting elements, and
in the step of laminating the first film, the first film is laminated on the convex portion so that an upper surface of the first film has a substantially spherical convex shape corresponding to the convex portion.

15. The manufacturing method of a display device according to claim 14,
wherein the first film is laminated by a vacuum film forming method.

16. The manufacturing method of a display device according to claim 14, further comprising
a step of laminating a second film formed by a material having a smaller refractive index than a refractive index of the first film right above the first film.

17. The manufacturing method of a display device according to claim 14,
wherein the step of forming the plurality of light emitting elements includes a step of forming a lower layer electrode of the light emitting elements, a step of laminating an insulating layer on the lower layer electrode, and a step of patterning the insulating layer so as to expose a region corresponding to the light emitting region of a surface of the lower layer electrode to form a pixel definition film that defines an area of the light emitting region,
in the step of forming the pixel definition film, the insulating layer is patterned such that the insulating layer remains in a partial region of a region corresponding to the light emitting region of the surface of the lower layer electrode, and
the convex portion is formed by laminating an organic layer and an upper layer electrode of the light emitting elements on the insulating layer that remains.

18. The manufacturing method of a display device according to claim 14, further comprising
a step of forming a via electrically connecting a lower layer electrode and a further lower layer circuit of the light emitting elements before the step of forming the plurality of light emitting elements,
wherein, in the step of forming the via, the via is formed such that an upper end of the via protrudes above a surface of the insulating layer on which the via is formed, and
the convex portion is formed by laminating the lower layer electrode, the organic layer, and the upper layer electrode of the light emitting elements on the via protruding from the surface of the insulating layer.
